(19) United States
(12) Patent Application Publication
(10) Pub. No.: US 2010/0314804 A1
(43) Pub. Date: Dec. 16, 2010

(54) METHOD FOR THE PRODUCTION OF SEMICONDUCTOR RIBBONS FROM A GASEOUS FEEDSTOCK

(76) Inventors: Antonio Vallera, Lisboa (PT); Joao Serra, Carcavelos (PT); Jorge Maia Alves, Oeiras (PT); Miguel Brito, Pragal (PT)

Correspondence Address: Pearl Cohen Zedek Latzer, LLP, 1500 Broadway, 12th Floor, New York, NY, 10036, US

(21) Appl. No.: 12/675,443

(22) PCT Filed: Aug. 31, 2007
(86) PCT No.: PCT/PT2007/000038

§ 371 Date: Aug. 23, 2010

(51) Int. Cl. C23C 16/24; C23C 16/01

(52) U.S. Cl. 264/430; 264/81

(57) ABSTRACT

The present invention provides a method for the production of semiconductor ribbons using exclusively a gaseous feedstock. A fine powder of semiconductor material is produced by decomposition, within the gas phase, of a gaseous feedstock. A layer of this semiconductor powder is uniformly distributed, compressed and flattened over a planar substrate, which is continuously moving in one direction. This said layer of semiconductor powder is, in the following stage, heated to a temperature sufficient to decompose the said gaseous feedstock on its surface. A continuous flow of the said gaseous feedstock over said powder layer is ensured so that a solid plate of semiconductor material grows over the said layer of semiconductor powder. After the growth stage, during which the solid plate has grown to a convenient thickness, the said solid plate of semiconductor material is separated from the said layer of semiconductor powder and substrate. This self supporting plate is then heated to a high temperature in an atmosphere containing gaseous feedstock to complete its growth and become a ribbon with the appropriate structural properties for further processing. The present invention is applicable, for example, in the industry of silicon ribbon production for photovoltaic application.

### 1. FIELD OF THE INVENTION

The present invention relates to a process for the continuous growth of ribbons of semiconductor material from a gaseous feedstock.

### 2. STATE OF THE ART

Although the process here disclosed may apply to several semiconductor materials, presently the dominant material in the foreseen area of application (photovoltaics) is silicon, and we shall therefore refer especially to silicon in the following description of the state of the art.

In all present industrial processes, silicon reaches the high purity grade (necessary to applications such as solar cells) as a gas of the silane family, SiH₄₋ₙClₙ. In mainstream processes, the gas is then thermally decomposed into solid silicon in the form of granules or bars, which constitute commercial solid silicon feedstock. This feedstock is molten in a furnace, and allowed to crystallize into ingots, which are then sawn into wafers. Alternatively, molten silicon may be made to crystallize directly into silicon plates or ribbons, thus avoiding the cost and inefficiency of ingot sawing.

Presently, the base material, the crystalline silicon wafer, accounts for ˜75% of the cost of a solar cell. In spite of the current investment in new solar silicon feedstocks, which should increase the offer of silicon feedstock at lower prices, it is expected that future technologies of wafer production for solar cells will probably be based on techniques that use efficiently silicon feedstock, namely sheet, film or ribbon techniques.

The crystallization of a semiconductor material into a ribbon directly from the melt avoids material loss and reduces costs associated with the operation of cutting an ingot into wafers. Already in the early days of solar cells it was realized that ingot growth followed by wafering was a very wasteful process, and that ribbon growth techniques should be the right way to pursue. Although easy to enunciate, and attractive in principle, this problem proved very difficult to solve: most silicon sheet growth techniques have failed to demonstrate sufficient conversion efficiency (particularly due to impurities and to crystallographic lattice imperfections), production reliability and low cost. Although many methods have been proposed for the continuous, or semi continuous, growth of semiconductor ribbons, very few proved to be industrially viable.

Most ribbon growth methods use solid silicon feedstock as a starting point. The solid feedstock is molten, and shaped crystallization into a ribbon proceeds from the melt.

The method here described, however, was designed to produce high purity, low cost, self-supporting silicon sheet directly from the gas phase, thus bypassing costly present day processes of obtaining solid silicon feedstock through the thermal decomposition of chlorosilanes.

As we shall discuss below, the major difficulty in sheet production techniques that use a gaseous feedstock derive from the simple fact that a substrate is necessary: deposition of a solid plate from a gas requires a flat supporting surface. Usually the deposited film will be strongly adhering to the substrate; since detachment is then impossible, a low cost substrate must be used, and resulting solar cells are usually low quality. Detachment of grown films and re-use of high quality substrates is possible, by interposition of such sacrificial layers as electrochemical porous silicon, but costs are then high.

An alternative to existing techniques that might solve such problems is precisely what we set to seek, the result being a new process as disclosed here.

But let us first review the state of the art in silicon sheet/ribbon/film techniques with special emphasis on the ones more closely related to the subject of the invention we are disclosing.

2.1. Silicon Sheet from Solid Feedstock

Some of the techniques based on crystallization from molten silicon feedstock rely on the use of a crucible containing the silicon melt and of a die or other shaping device to control ribbon growth. Out of many proposed and researched alternatives, only two processes (EFG and String Ribbon) reached industrial production. In the EFG process, derived from U.S. Pat. No. 4,118,197 and previous related ones, the shape of the ribbon is determined by a die (or shaper) placed in the pool of melt contained in a crucible. The String Ribbon, derived from U.S. Pat. No. 4,661,200, requires a pair of strings that pass through the crucible containing the melt. These strings are used to stabilize the ribbon edges, and become incorporated into the ribbon.

Several other techniques of sheet growth from molten silicon feedstock rely on the use of a substrate over which solidification takes place. We mention the RGS technique (U.S. Pat. No. 4,670,096), where a moving substrate passes under a crucible containing the melt; the trailing film of liquid is allowed to solidify on the substrate. The ribbon thus produced detaches from its quartz substrate as temperature decreases. The SSP process (U.S. Pat. No. 4,690,797) uses zone melting of silicon pellets on quartz, but avoids strong interaction with the substrate.

2.2. Si Sheet/Ribbon/Film from the Gas Phase

Instead of growing sheet silicon starting from solid silicon feedstock, several attempts have been made to obtain ribbons directly from a gaseous feedstock.

The main problems derive from the simple fact that silicon sheet formation from the gas phase needs a substrate. We consider two types of substrates: (i) foreign substrates and (ii) silicon substrates.

Foreign substrates pose problems related to contamination, and to dislocation generation and plastic deformation due to thermally induced stress. Patent WO9949523, as an example, describes a method using ceramic silicon-carbide substrates as a supporting layer for silicon solar cells. Despite numerous attempts, no foreign substrate process has proved outstandingly attractive so far.

JP1080020 patent describes a technique to obtain a thin film of silicon that starts with deposition of fine amorphous silicon powder, at normal pressure, on a substrate. Silane (SiH₄) gas is introduced together with chlorine to create a combustion reaction under normal pressure. The fine amorphous silicon powder thus deposited on the substrate is later crystallized by laser heating. There is no detachment of the ribbon from the substrate.

Silicon substrates have in principle several advantages over foreign ones. There is no lattice mismatch, and no contamination—provided they are high purity and appropriate care is taken in their preparation. Deposition of silicon films on multicrystalline silicon substrates has been studied, particularly at the Fraunhofer Institut fur Solar EnergieSysteme (FhISE, Freiburg) [see reference below] and at the IMEC (Leuven) [see references below], and are examples of silicon growth on low-cost silicon substrates. Unfortunately, the results on cell quality versus process cost have not been sufficiently outstanding to encourage a fast path to an industrial phase. On the contrary, high quality has been reached in films by epitaxial chemical vapour deposition at high temperatures on single crystal wafers, but cost is then high. An approach to cost reduction is the detachment of the grown film from the substrate, so it can be reused (EP1024523). The best known process, initiated by Tayanaka (U.S. Pat. No. 6,326,280) and developed by Brendel (DE19730975) in particular, uses epitaxial growth (a high temperature, low pressure, high cost process) on a sacrificial layer of electrochemically produced porous silicon on Czochralski single crystal wafers. Films are good quality, but costs are high.

U.S. Pat. No. 4,027,053 describes a method of producing a ribbon of polycrystalline silicon using a gaseous source that permeates a layer of silicon granules on a quartz substrate. With heat applied, silicon deposited between the granules binds them together to form a polycrystalline ribbon. Although filed over 30 years ago, this method failed to reach industrial production. One of the reasons for this must have been the difficulty to control ribbon thickness to the thin dimension that is industrially interesting: it is in practice impossible to control temperature and gas gradients to limit granule coalescence to a thin layer that is still detachable from the substrate. Another problem is that molten zone recrystallization, needed to improve the crystal quality of such ribbons, is very unstable except for the very thick, uninteresting ones.

2.3. Other Techniques Based on Silicon Powders or Granules that Might be Relevant for Producing Silicon Ribbons

Silicon powders or granulates have been used in several techniques to grow silicon crystals. In most of them the powder or granulate is used simply as feedstock material for melting and feeding the crystallization system. The above mentioned methods of crystallization from the melt are examples of this use. In some cases, such as in SSP (U.S. Pat. No. 4,690,797), already mentioned, zone melting is used on silicon granules which become incorporated into a ribbon.

U.S. Pat. No. 4,407,858 patent discloses a method for producing films of sintered polycrystalline silicon by grinding initial silicon material in a non-oxygen-containing liquid. We suspect impurity problems are insoluble in this technique.

A method based on silicon powder that uses float zone melting for the formation of a silicon rod is described by JP5043376 and JP6199589. The method, however, is not applicable to produce ribbons.

### 2.4 Towards the Present Technique

The process being disclosed here aims at (i) using a gaseous feedstock (for the reasons explained above) as the only source of semiconductor material, and (ii) producing detachable self-supporting semiconductor ribbon, so that existing well developed techniques for high efficiency solar cells on wafers can be applied to the new base material, with presumed high acceptance by industry. The first choice means that no solid feedstock be used; the second choice means that the ribbon must be detached from its substrate.

The other guide-line is to preserve high purity, by avoiding contamination: most previous semiconductor ribbon processes failed because of poor material quality.

Low cost is another essential aim. In thermal deposition from a gaseous feeedstock, energy use is a very important factor; another factor is the cost of the equipment necessary to meet the process requirements. A process was therefore sought to produce high rates of deposition at the lowest temperatures possible and at ambient pressure. High rates of deposition are needed for the thicknesses required for self-sustaining ribbons. Lower temperatures mean less energy use and also less contamination from substrate or other furnace parts; but, on the other hand, and particularly when combined with high growth rates, they also mean worse crystallographic quality of the deposit. In the present process, the choice was definitely on low cost and high purity, completely waiving crystal quality. This is possible because of existing techniques, such as zone melting re-crystallization, that can produce high quality semiconductor ribbon material from poorly crystallized ribbon, provided purity has been preserved.

The crucial choice to make it all possible is the nature of the substrate over which deposition from the gas phase occurs. For purity preservation and mechanical reasons, the ideal substrate is a plate of high purity semiconductor, but detachment of the deposited film is then impossible. High purity foreign materials such as quartz or nitrides could be used, but detachment is again a problem, compounded with contamination. Several sacrificial layers have been tried to make detachment possible, but none has produced outstanding results (except perhaps the electrochemical porous silicon layer on single crystal substrates, but at a high cost).

The decision that originated the main inventive step of the present process was to study the behaviour of a layer of the very fine, nanometric semiconductor powder that is spontaneously produced by thermal decomposition of the gaseous feedstock in the gas phase. If such a layer is compressed and flattened over a solid slab of a non-contaminant material such as quartz, under the conditions of the here disclosed process, gas diffusion and decomposition within the powder is negligible, the deposition occurring therefore almost exclusively on top of the powder layer. The deposited ribbon is therefore easily detached from the supporting solid substrate via the powder layer. Most importantly, its thickness can be completely controlled by the amount of gas decomposed over the surface (which is essentially the volume of gas injected per unit surface area of produced ribbon), contrary to U.S. Pat. No. 4,027,053, the previous art closest to that being here disclosed.

Other advantages, over other techniques using particulate semiconductor, derive from the fact that this nanometric powder, being produced with the same gaseous feedstock used to grow the ribbon, (i) requires only one feedstock to be used (rather than gaseous plus solid), and, most importantly, (ii) high purity is preserved, since no solid feedstock handling external to the process is necessary. On the other hand, this nanometric powder having an exceedingly large specific area and high reactivity, must be produced within the process itself, in order to avoid external handling and contamination.

The problem of instability in the downstream step of molten zone recrystallization, necessary to improve crystal quality in ribbons produced from particulate material or any other of fine grain, had also to be addressed. Although the ribbon grown over the nanometric powder is more homogeneous and in principle less prone to failure during recrystallization than others incorporating solid feedstock granules, it was nevertheless found that a further step prior to recrystallization was needed to improve the failure rate. This step consists of heating to a high temperature the ribbon, after detachment from the substrate, in an atmosphere containing gaseous feedstock at lower concentration, so that both sides of the ribbon are exposed to the gas.

With this here described process, we believe a great improvement on previous art is achieved that may allow a path to competitive industrial production of semiconductor ribbons.

### REFERENCES

FhISE: “High-temperature CVD for crystalline-silicon thin-film solar cells”,
Faller, F. R.; Hurrle, A.;, IEEE Transactions on Electron Devices Volume 46, Issue 10, October 1999 Page(s):2048-2054
IMEC: “Progress in epitaxial deposition on low cost substrates for thin film crystalline silicon solar cells at IMEC”, Van Nieuwenhuysen, K.; Duerinckx, F.; Kuzma Filipek, I.; Van Gestel, D.; Beaucarne, G. and Poortmans, J.; Journal of Crystal Growth. Vol. 287: (2) 438-441; 2006. (Paper presented at the 16th American Conf. on Crystal Growth and Epitaxy, July 2005)
IMEC: “Epitaxial thin-film Si solar cells”, Beaucarne, G.; Duerinckx, F.; Kuzma Filipek, I.; Van Nieuwenhuysen, K.; Kim, H. and Poortmans, J.;. Thin Solid Films. Vol. 511-512: 533-542; 2006. (Paper from the E-MRS Spring Meeting Symposium F:Thin Film and Nano-Structure Materials for Photovoltaics; May 2005)

### 3. DISCLOSURE OF INVENTION

The process uses as only feedstock a substance, or mixture of substances, in the gas phase, containing the chemical elements that form the solid semiconductor upon thermal decomposition. This gaseous feedstock is first used to produce a fine powder of semiconductor material by thermal decomposition in the gas phase. A layer of this powder is uniformly distributed over a planar substrate, which transports the materials deposited on it into several process stages. This layer of semiconductor powder is compressed and flattened, so it presents a planar surface, and, in the following stage, heated to a temperature sufficient to decompose the gaseous feedstock on its surface. A continuous flow of gaseous feedstock over the surface of the said layer of semiconductor powder is ensured, so that a solid plate of semiconductor material starts to grow over the said layer of semiconductor powder. After the growth stage, during which the solid plate has grown to a convenient thickness, the said planar substrate and the powder layer are then separated from the grown plate. This detached, self-supporting solid plate, constitutes the ribbon. Powder non adherent to the ribbon is scraped away for re-use.

The powder layer acts therefore simultaneously as (i) a substrate for the growth of the semiconductor ribbon and as (ii) a sacrificial layer, providing a simple way to detach the ribbon from the substrate.

The detached ribbon is then heated to a high temperature, with both upper and lower surfaces exposed to an atmosphere containing gaseous feedstock, to gain the structural characteristics needed for successful further processing.

The final width of the ribbon is essentially determined by the width of the heated powder layer. The final thickness of the semiconductor ribbon is essentially determined by the ratio between (i) the volume of gas injected (per unit time) in the growth and post-detachment treatment stages, and (ii) the area of ribbon generated (per unit time).

The present invention provides a method for the production of semiconductor ribbons from a gaseous feedstock.

The present invention is applicable, for example, in the industry of silicon ribbon production for photovoltaic application.

### 4. BRIEF DESCRIPTION OF THE DRAWINGS

FIG. 1 is a schematic and simplified representation of an embodiment of an essential stage of the process, that of growth of the ribbon over the powder layer, in accordance with the present invention, in the case of continuous growth; and

FIG. 2 is a schematic and simplified representation of an embodiment of the essential stage of the process, that of growth of the ribbon over the powder layer, in accordance with the present invention, in the case of batch production;

### 5. DESCRIPTION OF THE PREFERRED EMBODIMENTS

The apparatus consists of a series of stages, corresponding to steps in the process. In the first stage, the gaseous feedstock, silane in hydrogen, is used to produce a fine powder of semiconductor material (silicon) by thermal decomposition in the gas phase. This semiconductor powder is uniformly spread and subsequently compressed and flattened, over a substrate constituted by contiguous quartz plates and moving at constant speed, by means of a vibrating blade and pressing piece.

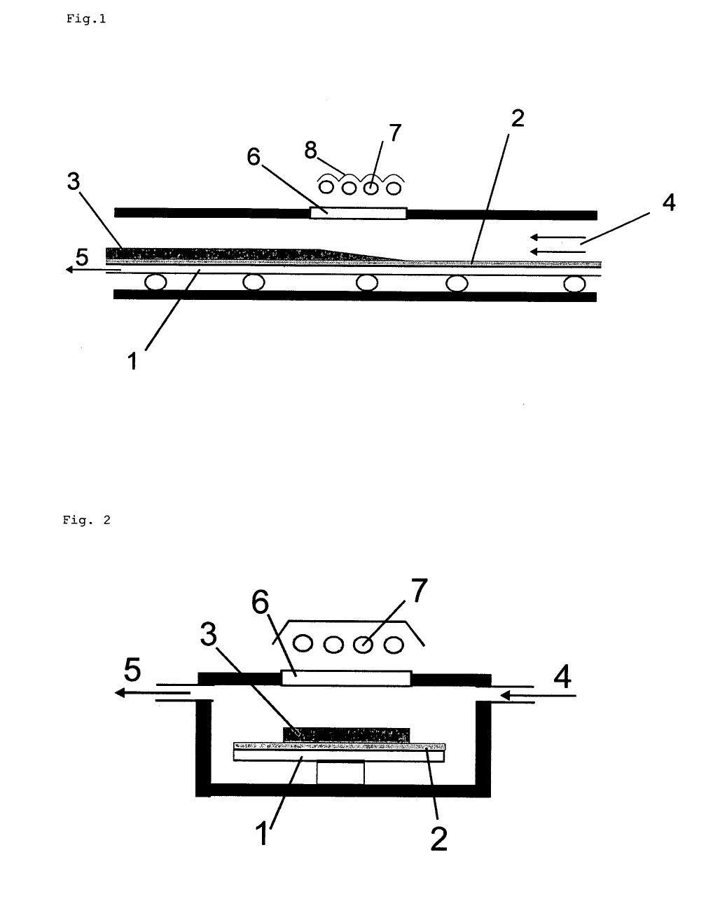

In the next stage, represented in FIG. 1, the compressed and flattened powder layer (2) over the substrate (1) is heated by radiation from halogen lamps (7) through a quartz window (6). The gaseous feedstock (4) was made to flow over the heated surface, causing deposition of solid semiconductor material (3), silicon, over the heated surface. The deposited material thickens as the motion transports it under the radiation heaters.

In the third stage, the self-supporting (silicon) ribbon is detached from the (quartz) substrate, and is ready for further processing. The substrate and the powder can be re-used.

In the fourth stage, the detached ribbon is heated to a temperature of about 120° C. by the concentrated light of halogen lamps in an atmosphere containing silane with a concentration under 1%.

In the embodiment for batch production the main differences derive from the fact that the substrate (1) is a single plate of quartz and does not move at constant speed throughout the different stages. It remains stationary in the central stage below the quartz window (6), illustrated in FIG. 2. Radiation from halogen lamps (7) and inlet gas flow (4) must ensure an approximately uniform growth of the deposited section of semiconductor (3) (silicon) ribbon on top of the flattened powder layer (2). The first, third and fourth stages are similar in principle, with the necessary adaptation for a single plate substrate.

Having thus described a preferred embodiment of the present invention, it should be noted by those skilled in the art that the within disclosures are exemplary only and that various other alternatives, adaptations and modifications may be made within the scope of the present invention. Accordingly, the present invention is not limited to the specific embodiments as illustrated herein.

1. A process for the growth of ribbons of semiconductor material exclusively from a gaseous feedstock comprising:
producing a fine powder, with particle size below 50 micron, of the semiconductor by gas phase decomposition of the gaseous feedstock;
spreading uniformly and compressing said fine powder on a plane substrate made of a non contaminant material to produce a flattened layer of compressed powder of said semiconductor;
heating said powder layer to a surface temperature sufficient to cause decomposition of said gaseous semiconductor feedstock;
causing the gaseous feedstock to flow over the surface of said heated powder layer so that deposition over it of a solid semiconductor film occurs, such film being allowed to thicken to form, on top of said powder layer, a ribbon capable of self support;
using said powder layer as a sacrificial layer to mechanically detach the deposited semiconductor ribbon from the substrate;
subjecting said detached ribbon to a high temperature treatment with both surfaces in contact with said gaseous feedstock in order to gain the structural characteristics needed for successful processing.

2. A process in accordance with claim 1 wherein the process is continuous.

3. A process in accordance with claim 1 wherein said heating is carried out by applying radiant energy to said semiconductor powder layer and to said detached ribbon.

4. A process in accordance with claim 1 wherein said powder layer is made of silicon and said gaseous feedstock contains silane.

5. A process in accordance with claim 4 wherein the powder is produced by homogeneous thermal decomposition in the gas phase, using a gaseous mixture wherein the silane concentration is in the range of 10 to 100%, the diluting gas being hydrogen.

6. A process in accordance with claim 1 wherein (i) the surface temperature of the heated silicon powder layer is in the range of 400C to 1000C, and (ii) the gas is fed at ambient pressure with silane concentrations in the range of 10 to 90% in hydrogen, resulting in growth rates for the solid layer in the range of 2 to 20 micron per minute.

7. A process in accordance with claim 1 wherein the high temperature treatment is performed at ambient pressure, at a temperature of about 120° C., with a silane concentration below 1%.

8. A process in accordance with claim 1 wherein the process is in batch mode.
